(19) United States
(12) Patent Application Publication
(10) Pub. No.: US 2026/0330100 A1
(43) Pub. Date: Oct. 22, 2026

(54) SYSTEMS AND METHODS FOR ORGANIZING MEDICATION STORAGE CABINETS

(71) Applicant: Omnicell, Inc., Fort Worth, TX (US)

(72) Inventors: Aatish Sethi, Suwanee, GA (US); Rich Lau, Dix Hills, NY (US); Rajeev Tiwari, San Jose, CA (US); Arulvelan Mani, Mars, PA (US); Thomas Job Jeffrey Kannankeril, South Windsor, CT (US)

(73) Assignee: Omnicell, Inc., Fort Worth, TX (US)

(21) Appl. No.: 19/180,390

(22) Filed: Apr. 16, 2025

(51) Int. Cl. G06F 30/27; A47B 88/969

(52) U.S. Cl. CPC G06F 30/27; A47B 88/969

(57) ABSTRACT

A system for determining an optimal configuration for a medication storage cabinet, the system comprising: one or more processors; and a memory storing instructions that, when executed by the one or more processors, cause the system to perform operations comprising: collecting cabinet data and medication data, preprocessing the collected data, wherein the preprocessing includes cleaning, normalizing, and transforming the collected data, performing feature engineering on the preprocessed data to generate engineered features, selecting relevant features, performing dimensionality reduction on the preprocessed data, and training a machine learning model using the selected features, wherein the machine learning model includes a random forest model for generating an initial cabinet configuration and a reinforcement learning model for continuous real-time optimization; generating an optimal configuration for the medication storage cabinet based on the trained machine learning model; and receiving real-time updates and incorporating feedback to refine the generated optimal configuration.

### TECHNICAL FIELD

Aspects of the present disclosure generally relate to cabinet organization systems and methods, and more particularly, to automated systems and methods for organizing medication or medication storage cabinets leveraging data analysis and optimization algorithms.

### BACKGROUND

Reference may be made herein to other United States patents, foreign patents, and/or other technical references. Any reference made herein to other documents is an express incorporation by reference of the document so referenced in its entirety.

Traditional medication storage cabinets consist of several drawers, each containing bins for storing the medication. Conventional organization systems and methods for assigning medications to bins within the cabinet drawers, which have traditionally been done manually, are inherently inadequate, largely stemming from their limited and simplistic functionalities. Manual allocation of medications to individual bins is both time-consuming and susceptible to user error. Further, once a cabinet configuration has been determined, the same configuration is often used across several cabinets within a system. This “clone” approach is advantageously simplistic but offers little customizability where different configurations or adjustments are required or would be beneficial. The “clone” approach imposes rigid constraints by mandating exact assignments across cabinets, which may not be ideal for all medication storage cabinets and may be inefficient, especially when requiring significant manual intervention.

Deficiencies of existing solutions are particularly pronounced for complex cabinet configurations. For example, an intricate cabinet may include multiple bins or cells and attached auxiliary cabinets. These added complexities amplify the time and effort needed for manual medication assignment, exacerbating user challenges.

Moreover, the conventional, manual process of assigning medications to cabinet drawers is further hindered by the necessity for multiple assignments at various stages of the overall process. This task is repetitive and arises during different phases of the cabinet assignment process, from the initial stages of cabinet ordering and on through the lifespan of a cabinet while on-site. Consequently, the conventional process fails to harness data efficiently, leading to increased delays and errors. Each medication assignment consumes additional time and effort, but also elevates the risk of errors or inconsistencies. The manual nature of the process renders it susceptible to human errors, further complicating workflow. Furthermore, the lack of an optimized, data-driven approach undermines the overall effectiveness of the assignment process, resulting in suboptimal storage and access arrangements.

To overcome these challenges, there is a need for a solution that not only automates the assignment process but also leverages data analysis to optimize organization, storage and access arrangements. By integrating data-driven methodologies, the proposed systems and methods can mitigate delays, eliminate redundancies and errors, and enhance overall efficiency throughout the cabinet's lifecycle.

### SUMMARY

Techniques described herein are directed to automated systems and methods for organizing medication storage cabinets leveraging data analysis and optimization algorithms. Embodiments of the present disclosure may provide various systems and methods for improving the efficiency of medication organization within medication storage cabinets. In particular, embodiments may provide for determining an optimal configuration for a medication storage cabinet. The optimal configuration for a medication storage cabinet may be determined by training and using machine learning using one or more of the systems, methods, and/or components described herein. Combinations of the systems, methods, and/or components may be implemented for optimally organizing medication storage cabinets.

An example embodiment of the present disclosure may be a system system for determining an optimal configuration for a medication storage cabinet, the system including: one or more processors; and a memory storing instructions that, when executed by the one or more processors, cause the system to perform operations including: collecting cabinet data and medication data, preprocessing the collected data, wherein the preprocessing comprises cleaning, normalizing, and transforming the collected data, performing feature engineering on the preprocessed data to generate engineered features, selecting relevant features, performing dimensionality reduction on the preprocessed data, and training a machine learning model using the selected features, wherein the machine learning model comprises a random forest model for generating an initial cabinet configuration and a reinforcement learning model for continuous real-time optimization; generating an optimal configuration for the medication storage cabinet based on the trained machine learning model; and receiving real-time updates and incorporating feedback to refine the generated optimal configuration.

In another embodiment, the cabinet data comprises bin capacity, temperature zones, and proximity to cooling units, and the medication data comprises volume, temperature sensitivity, security level, hazardous status, and access frequency.

In another embodiment, preprocessing the collected data further comprises handling missing values through statistical imputation, performing error correction, and performing outlier detection.

In another embodiment, performing feature engineering comprises generating interaction features.

In another embodiment, the step of selecting relevant features comprises applying Principal Component Analysis (PCA) to reduce data dimensionality.

In another embodiment, the random forest model is configured to provide an initial configuration by analyzing historical medication placement data and usage patterns.

In another embodiment, the reinforcement learning model is configured to continuously refine the optimal configuration by monitoring real-time data from sensors placed within the cabinet. The system of claim 1, wherein generating the optimal configuration comprises assigning medications to specific bins based on accessibility needs, such that frequently accessed medications are stored in easily accessible bins.

In another embodiment, the processor is further configured to generate alerts based on an analysis via the reinforcement learning model to notify users when a medication should be relocated due to updated usage patterns.

In another embodiment, the machine learning model further comprises a deep learning model to predict future medication placement needs based on seasonal variations in medication demand.

An example embodiment of the present disclosure may be a method a method for determining an optimal configuration for a medication storage cabinet, the method comprising: collecting cabinet data and medication data, preprocessing the collected data, wherein the preprocessing comprises cleaning, normalizing, and transforming the collected data, performing feature engineering on the preprocessed data to generate engineered features, selecting relevant features, performing dimensionality reduction on the preprocessed data, and training a machine learning model using the selected features, wherein the machine learning model comprises a random forest model for generating an initial cabinet configuration and a reinforcement learning model for continuous real-time optimization; generating an optimal configuration for the medication storage cabinet based on the trained machine learning model; and receiving real-time updates and incorporating feedback to refine the generated optimal configuration.

In another embodiment, the cabinet data comprises bin capacity, temperature zones, and proximity to cooling units, and the medication data comprises volume, temperature sensitivity, security level, hazardous status, and access frequency.

In another embodiment, preprocessing the collected data further comprises handling missing values through statistical imputation, performing error correction, and performing outlier detection.

In another embodiment, performing feature engineering comprises generating interaction features.

In another embodiment, the step of selecting relevant features comprises applying Principal Component Analysis (PCA) to reduce data dimensionality.

In another embodiment, the random forest model is configured to provide an initial configuration by analyzing historical medication placement data and usage patterns.

In another embodiment, the reinforcement learning model is configured to continuously refine the optimal configuration by monitoring real-time data from sensors placed within the cabinet.

In another embodiment, generating the optimal configuration comprises assigning medications to specific bins based on accessibility needs, such that frequently accessed medications are stored in easily accessible bins.

In another embodiment, the method further comprises generating alerts based on an analysis via the reinforcement learning model to notify users when a medication should be relocated due to updated usage patterns.

In another embodiment, the machine learning model further comprises a deep learning model to predict future medication placement needs based on seasonal variations in medication demand.

The above summary has outlined, rather broadly, some features and technical advantages of the present disclosure so that the detailed description that follows may be better understood. Additional features and advantages of this disclosure will be described below. It should be appreciated by those skilled in the art that this disclosure may be readily utilized as a basis for modifying or designing other systems and structures for carrying out the same or similar purposes of the present disclosure. It should also be realized by those skilled in the art that such equivalent systems and structures do not depart from the teachings of the disclosure as set forth in the appended claims. The novel features, which are believed to be characteristic of this disclosure, both as to its organization and method of operation, together with further features and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

The features, nature, and advantages of the present disclosure will become more apparent from the detailed description set forth below when taken in conjunction with the drawings, in which:

FIG. 1 depicts an illustrative example of a medication storage cabinet configuration according to an embodiment of the present disclosure;

FIGS. 2A-2H depict illustrative examples of drawer configurations within a medication storage cabinet according to an embodiment of the present disclosure;

FIG. 3 depicts an illustrative example of a system for determining a medication storage cabinet configuration according to an embodiment of the present disclosure;

FIG. 4 depicts an illustrative example of a flow diagram for a system for determining a medication storage cabinet configuration according to an embodiment of the present disclosure;

FIG. 5 depicts an illustrative example of a flow chart of a method for determining a medication storage cabinet configuration according to an embodiment of the present disclosure;

FIG. 6 depicts an illustrative example of a flow chart of a method for performing Principal Component Analysis (PCA) according to an embodiment of the present disclosure;

FIG. 7 depicts an illustrative example of a flow chart of a method for performing Recursive Feature Elimination (RFE) according to an embodiment of the present disclosure;

FIG. 8 depicts an illustrative example of a flow chart of a method for performing feature importance scoring according to an embodiment of the present disclosure;

FIG. 9 depicts an illustrative example of a flow chart of a method for performing Random Forest (RF) model development according to an embodiment of the present disclosure;

FIG. 10 depicts an illustrative example of a flow chart of a method for performing Reinforcement Learning (RL) model development feature importance scoring according to an embodiment of the present disclosure; and

FIG. 11 depicts an illustrative example of another system for determining a medication storage cabinet configuration according to an embodiment of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts disclosed herein. It will be apparent, however, to those skilled in the art that these concepts may be practiced without these specific details. In some instances, well-known features may be omitted or simplified in order to not obscure the embodiment being described.

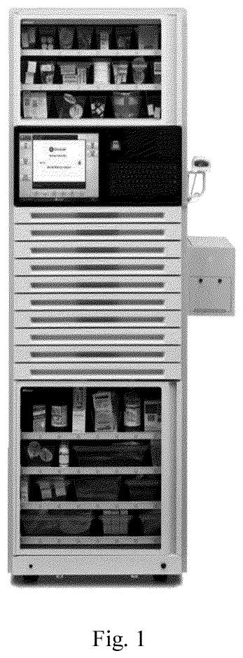

FIG. 1 depicts an illustrative example of a medication storage cabinet configuration according to an embodiment of the present disclosure. Medication storage cabinet or cabinet 100 is configured for storage of medications, varying in, for example, without limitation, size, form, special access restrictions, etc. Many medications require different types of storage conditions, especially to prolong their lifespan or longevity. Precise control of storage conditions is critical to long and short term medication storage, and may include control over temperature, humidity, light exposure, etc. For example, without limitation, unopened insulin is typically stored in a temperature-controlled environment, such as a refrigerator, for a prolonged period of time (typically up to approximately one year), and once opened, may be kept at room temperature for a shorter period of time (typically up to approximately one month). Additionally, many medications, especially tablets and capsules, may be sensitive to environments with high humidity, and should be kept in dry environments to prevent degradation. Restricted access to certain medications may also be required, especially with regards to controlled substances, such as analgesics. Space considerations, frequency of use, combined utilization of medication, etc. are other factors to consider when determining optimal medication storage, and changes in storage factors over time may be considered when determining a storage configuration.

Cabinet 100 may include frame 102, shelves 104, drawers 106, and bins 110. Cabinet 100 may also include user input/output (I/O) interface 112, which may be used by the user to engage cabinet 100 when storing and retrieving medication stored within cabinet 100. As is well known in the art, user I/O interface 112 of cabinet 100 may be in communication with a processor to receive various inputs from a user (e.g., when a user is attempting to store medication to or retrieve medication from cabinet 100) and/or to provide an audible, visual, mechanical, or other output to the user (e.g., to provide information to the user). As such, user I/O interface 112 may include, for example, one or more user input devices, fingerprint reader 116, keyboard 118, numpad 120, and scanner module 122, and any other known user input devices, such as a computer mouse, a joystick, a microphone, a camera, a pointing device, a controller, a biometric device, a motion sensor, etc. Accordingly, user I/O interface 112 may, in some example embodiments disclosed herein, provide means for user control of embodiments of the present invention. User I/O interface 112 may also include one or more user output devices, such as screen 114. The user output devices may also include, for example, without limitation, printers, speakers, headphones/earphones, projectors, virtual reality (VR) headsets, haptic devices, etc., and may be used to transmit information to a user. Screen 114 may be a standard display screen, a touch screen display, and the like and may serve to provide an additional user input means. In some example embodiments in which the invention is embodied as a server, cloud computing system, or the like, aspects of user I/O interface 112 may be limited or user I/O interface 112 may not be present. In some example embodiments, one or more aspects of user I/O interface 112 may be implemented on a user terminal. Accordingly, regardless of implementation, user I/O interface 112 may provide input and output means to facilitate handling, storing, retrieving, organizing, transporting, or delivery of medication in accordance with one or more example embodiments disclosed herein. Moreover, optionally, off-system user I/O devices known in the art (not shown) may also be used with cabinet 100, and may communicate with cabinet 100 via wired, wireless, or any other means known in the art. Off-system user I/O devices may be used in combination with user I/O interface 112, or as a standalone user interface system. Additionally, cabinet 100 may not include user I/O interface 112 when off-system user I/O devices are in use, providing for additional storage within cabinet 100.

Cabinet 100 may include one or more shelves 104, where medication may be stored individually in bins 110, in their own packaging, etc. Shelves 104 may be kept behind doors 124, where doors 124 may be transparent, opaque, hinging, sliding, etc. Separate doors may be used to segregate various sections of cabinet 100. For example, upper section 126 may be used for infrequently used items, while lower section 128 may be used for items having specific temperature requirements.

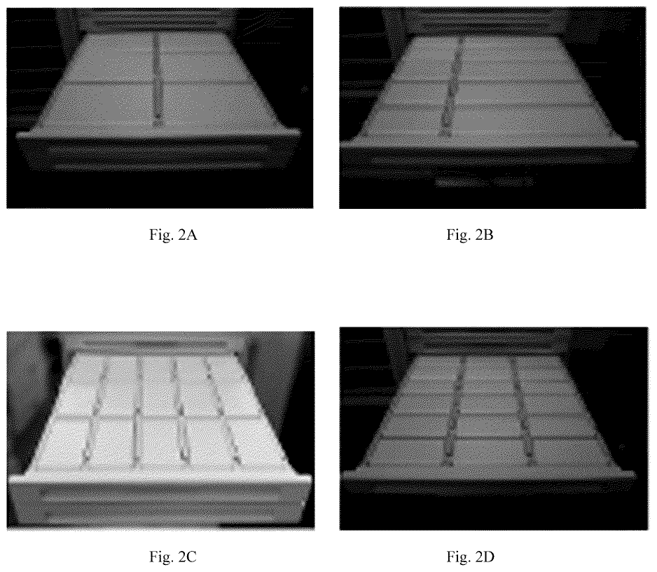

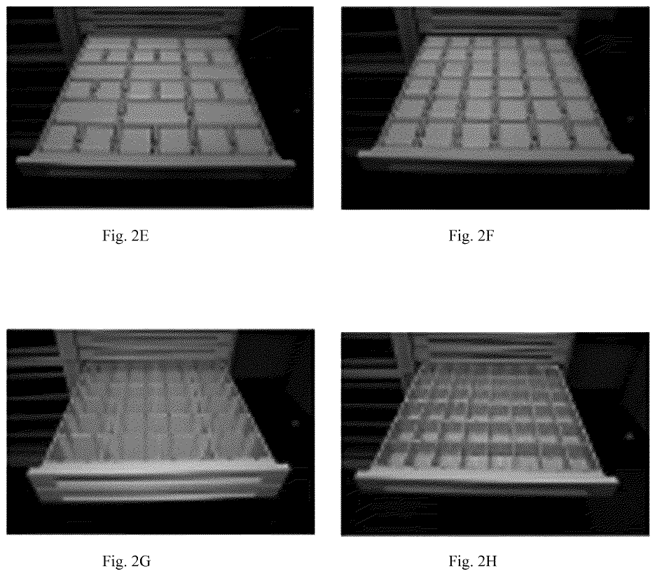

Cabinet 100 may also include drawers 106 for additional storage customizability. Drawers 106 may have uniform dimensions as shown such that drawers 106 may be interchangeable such that they may easily be removed and replaced with drawers having different configurations (to be described below with reference to FIGS. 2A-2H). Alternatively, drawers 106 may have different heights and widths, dependent upon the needs of the facility and/or user/administrator.

FIGS. 2A-2H depict illustrative examples of medication cabinet drawer configurations according to an embodiment of the present disclosure. It should be noted that the configurations shown in FIGS. 2A-2H are for exemplary purposes, and various other drawer configurations may be used and are within the scope of the present disclosure. Medication cabinet drawer configurations may include, for example, locking lid drawers as shown in FIGS. 2A-2F and open configurable drawers as shown in FIGS. 2G-2H. Drawer configurations may include additional features dependent upon the needs of the facility and/or user and are highly customizable. For example, without limitation, some drawers may have increased insulation, temperature control, individual lighting controls, moisture or humidity controls, etc. A configuration of a particular drawer may also be altered according to the needs of the facility and/or user.

Drawer configurations may take up one or more slots within a medication storage cabinet dependent upon the height of the drawer. For example, FIG. 2A, FIG. 2C and FIG. 2G show double slot drawers configured for two slots within a medication cabinet, while FIG. 2B, FIGS. 2D-2F and FIG. 2H show single slot drawers configured for one slot within a medication cabinet. As will be appreciated by one skilled in the art, drawers of lesser or greater thickness are also within the scope of the present disclosure.

As shown in FIGS. 2A-2H, the drawers comprise several bins for storing the medication. The bins within the drawers may be of various shapes and sizes. For example, the drawers may have bins that are all the same size and that are evenly distributed in two columns, as shown in the 6-bin configuration of FIG. 2A. The drawers may also be in an offset configuration, with smaller and larger bins, as shown in the 10-bin configuration of FIG. 2B. As shown in the 15-bin configuration of FIG. 2C, bins may be of greater depth than width; and as shown in the 18-bin configuration of FIG. 2D, bins may be of greater width than depth. Each row of bins within a drawer may be of different sizes, as shown in the 27-bin configuration of FIG. 2E. Additionally, drawers may include many small-sized bins, such as in the 36-bin locking lid configuration of FIG. 2F, the 24-bin open configuration of FIG. 2G, and the 48-bin open configuration of FIG. 2H.

In the foregoing descriptions and examples the customer referred to herein may be any facility for storing medication, such as a pharmacy, hospital, doctor's office, etc.

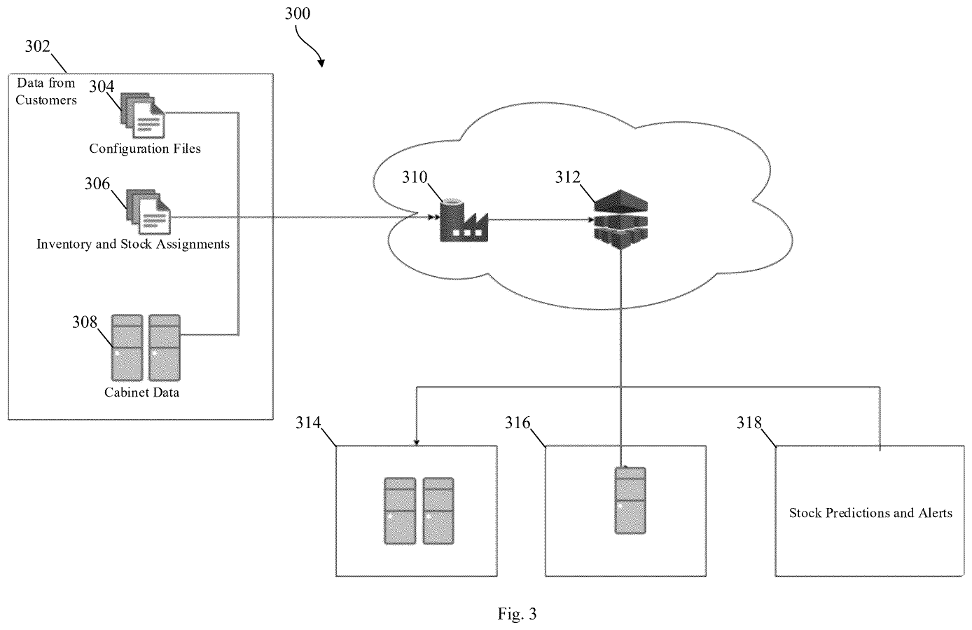

FIG. 3 depicts an illustrative example of a system 300 for determining a medication storage cabinet configuration according to an embodiment of the present disclosure. Customer data 302 may be input into medication configuration system 300 for processing to determine the medication storage needs of a customer. Customer data 302 may include configuration files 304 (e.g., . . . ), medication inventory and stock assignment data 306, and present cabinet configurations data 308, along with any other data or criteria set by the customer. For example, without limitation customer data 302 may include medication inventory for an entire facility, specific stock areas within the facility, historic inventory and medication stock assignment data, medication storage cabinet configuration data (including cabinet locations within the facility and cabinet, cell, drawer, and bin configuration, etc.), changes in hardware configuration data, usage pattern data, etc. Data collection may be an ongoing process throughout the lifecycle of a storage cabinet within a facility for dynamic updates to a medication configuration and/or organization system 300, ensuring up-to-date optimization of medication storage, and may be collected at different frequencies depending on the needs of the customer. For example, without limitation, customer data 302 may be collected during initial installation and setup of cabinet systems, and may be collected several times a day, on a daily basis, on a weekly basis, etc. Customer data 302 may also be specific to different areas within a facility. For example, without limitation, areas within a facility may be separated based on specialty area (e.g., pediatrics, oncology, orthopedics, etc.) where each specialty area has separate requirements for medication storage. Customer data 302 may alternatively be generalized for a facility for bulk storage of medication or medication that is not specific to a specialty. Historical customer data 302 may also be collected, including any data collected over short or long time periods, and may be used to determine trends in medication storage and inventory.

Several different types of customer data 302 may be collected from the customer site in order to determine optimal medication storage cabinet assignments and/or configurations. Each different type of data may require a different frequency of collection. Hardware configuration data 304 includes cabinet, drawer, bin, and storage dimensions and factors, and may be collected whenever there is a change to the hardware configuration of the customer site, such as an addition or removal of a cabinet or restructuring of an organization system. Medication inventory and stock assignment data 306 may include, for example, medication inventory, size, type, dimensions, environmental restrictions (e.g., temperature, humidity, light exposure, etc.), and any other similar types of data and/or restrictions. Medication inventory and stock assignment data 306 may be collected during installation, daily according to daily medication usage, and/or at any other frequency desired by the customer (e.g., weekly, monthly, etc.). Medication storage cabinet assignments/configuration data and medication usage pattern data may be extracted from present cabinet configurations data 308. Medication storage cabinet assignments/configuration data and medication usage pattern data may include medication assignments and/or cabinet configurations performed, medication assignment and/or cabinet configuration changes, dispensing of medication, return of medication, and temporal or historical usage data, and may be obtained frequently throughout the lifecycle of a cabinet system and/or at any frequency desired by the customer. Additional miscellaneous data may also be collected, including stock areas, areas assigned to cabinets, and any additional data not included in the previous categories. This may also include data collected based on a specialty area. All of the aforementioned data may be considered customer data 302.

Customer data 302 may be ingested for processing via processor 310. System 300 may also include processor 312 for employing or implementing Artificial Intelligence (AI) and Machine learning (ML) techniques for processing customer data 302. Customer data 302 may be input into new AI and/or ML models or input into AI and/or ML models trained in previous medication configuration iterations. For example, without limitation, a medication storage cabinet configuration proposal may be requested by a customer. Medication inventory and stock area based medication data may be collected from the customer and ingested by processor 310. AI and/or ML techniques may be used by processor 312 to process a customer's data along with historical data and generate one or more medication storage cabinet configurations 314. Exemplary medication location assignments 316 may also be generated for assigning each medication to a certain location and/or storage cabinet within the facility. To do so, customer and stock area data may be ingested by processor 310 and AI and/or ML techniques at processor 312 may be used to propose a medication location assignment 316 for each medication. AI and/or ML techniques performed by processor 312 may also be used with existing and historical data ingested by processor 310 to provide a proposal for a new location assignment, and instructions on how to perform the assignment. System 300 may also be used to generate stock predictions and alerts 318 based on historical data and usage patterns to prevent low inventory situations or excessive restocking.

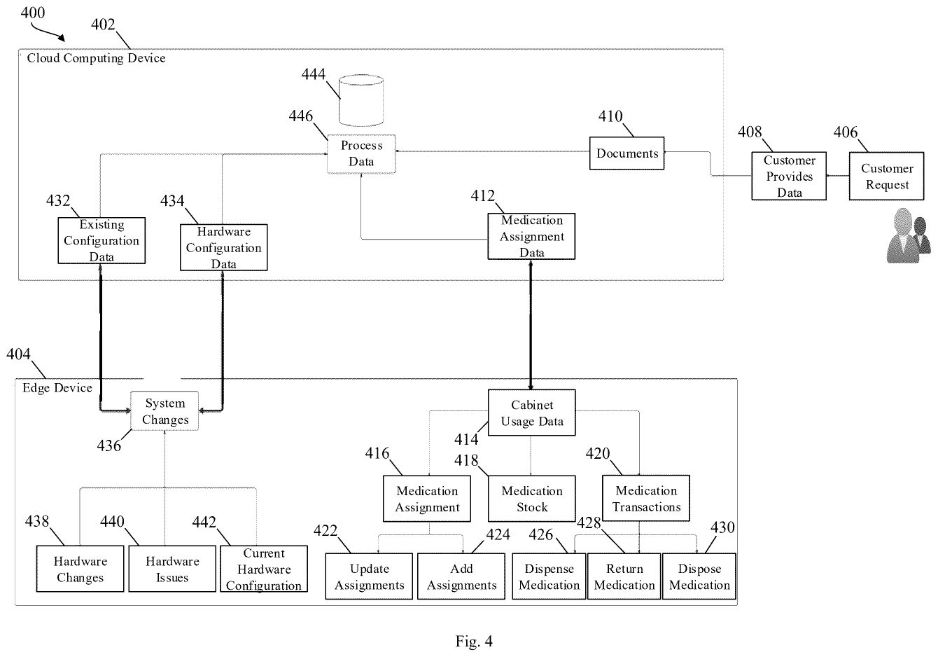

FIG. 4 depicts an illustrative example of a flow diagram for a computing system 400 for determining a medication storage cabinet configuration according to an embodiment of the present disclosure. The flow diagram of FIG. 4 also illustrates an example of synching data with cloud computing device 402 and using data from cloud computing device 402 at edge device 404. Specifically, system 400 comprises one or more cloud computing devices 402 and edge device 404. Cloud computing device 402 may be any known cloud-based computing device (e.g., computer, processor, server, etc.) that communicates with any known cloud-based hosting devices (not shown) within any known cloud-based system, and that shares resources, applications, and data with the cloud-based hosting devices and/or other cloud-based computing devices within the cloud-based system. Edge device 404 may be an individual cabinet within a facility associated with cloud computing device 402. As will be appreciated by one of skill in the art, a single cloud computing device 402 may communicate with multiple edge devices 404. Alternatively, each edge device 404 may be associated with a single or multiple cloud computing device 402. An exemplary edge device 404 may be cabinet 100 of FIG. 1.

The process starts at 406 where customers may make a request for a cabinet configuration. The request may be a manual request based on specific information to be provided by the customer to edge device 404, or an automated request based on historical usage data, new usage patterns, etc. At 408, the customer provides medication data (e.g., inventory, size, type, dimensions, environmental restrictions (e.g., temperature, humidity, light exposure, etc.), and any other similar types of data and/or restrictions) for the stock areas, along with any other relevant usage data to cloud computing device 402 by completing and submitting forms or documents 410 to cloud computing device 402. Simultaneously, data may be continuously synched from edge device 404 to cloud computing device 402 via any known wired or wireless connection.

Existing medication assignment data 412 may include data based off cabinet usage data 414 collected by edge device 404 and transmitted to cloud computing device 402. Cabinet usage data 414 may include data collected regarding performing medication assignments 416, adding medication stock or restocking 418, and conducting medication transactions 420. Performing medication assignments 416 may include updating existing medication assignments 422 and adding new medication assignments 424. Conducting medication transactions 420 may include dispensing of medications 426, returning medications 428, and disposing medications 430. Cabinet usage data 414 may be collected over long or short time periods, and may also be instantaneously collected when a request for cabinet configuration is made.

Cloud computing device 402 may also collect existing configuration data 432 and hardware configuration modification data 434 from edge device 404. Existing configuration data 432 and hardware configuration modification data 434 may be continuously gathered from edge device 404 based on changes to the system 436 and continuously transmitted to cloud computing device 402. Changes to the system 436 may include, for example, without limitation, hardware changes 438, hardware issues 440, and current hardware configuration 442. Existing configuration data 432, hardware configuration modification data 434, existing medication assignment data 412, and configuration request data of documents 410 may be accumulated and stored in database or datastore 444. At 446, cloud computing device 402 may process data collected in datastore 444 to determine an optimal medication storage cabinet configuration. The method for determining an optimal medication storage cabinet configuration is further explained below.

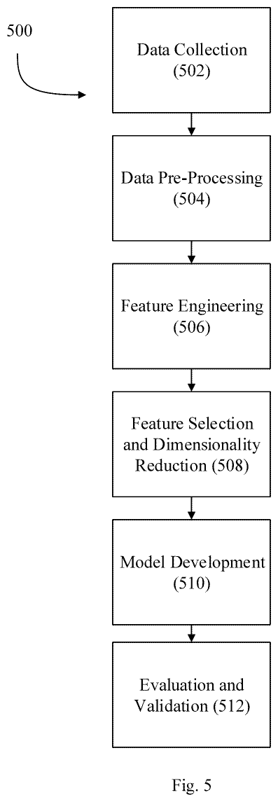

FIG. 5 depicts an illustrative example of a flow chart of a method 500 for determining a medication cabinet configuration according to an embodiment of the present disclosure. The method starts at step 502 where data may be collected from a user or customer for processing. Such user data may include medication data and cabinet data. Medication data may include, for example, without limitation, volume: a physical size of the medication packaging; temperature sensitivity: whether the medication requires refrigeration or specific environmental conditions; security level: whether the medication requires storage in a secure location (e.g., the medication is a controlled substance); hazardous status: whether the medication is hazardous and requires special handling; access frequency: how often the medication is retrieved; etc. Cabinet data may include, for example, without limitation, bin availability and capacity: storage volume available for each bin of the cabinet; temperature/environmental zones: temperature and/or environmental characteristics of each bin (e.g., refrigerated, unrefrigerated, humidified, etc.); proximity to cooling units: a distance of each bin from cooling areas for temperature-sensitive medications; bin security access: security codes to access such bins; hazardous medication bins: identification of bins containing hazardous medications; etc.

At step 504, the collected data may undergo initial processing or pre-processing, including cleaning, normalizing, and transforming the data. Several algorithms may be used to process the input data. In one embodiment, data cleaning may include handling missing values, error correction, and outlier detection and removal. Handling missing values may include utilization of statistical techniques (e.g., mean imputation or median imputation) to impute missing data points (e.g., medication volumes or bin capacities). Missing values may also be removed if the values are non-critical. Error correction may include utilization of reference databases or subject matter expertise to correct detected errors in data entry (e.g., impossible medication volumes). Outlier detection and removal may include flagging outliers (e.g., extremely high medication volumes or low access frequencies) for correction or removal based on client preferences.

The data may then be normalized and standardized, for example, via Min-Max scaling and/or Z-score normalization. Min-Max scaling may be used to scale data features to a common range, such as [0,1]. As such, large values (e.g., bin capacity) will not dominate smaller values (e.g., security level) during optimization. For each value in the dataset, the minimum value (Xₘᵢₙ) and the maximum value (Xₘₐₓ) are determined. For each value X in the dataset, a Min-Max scaling formula is applied according to:

$${X}_{scaled} = \frac{X - {X}_{min}}{{X}_{max} - {X}_{min}}$$

The original values X in the data set are replaced with the scaled values X_{scaled}. The resulting dataset will thus be normalized, facilitating better comparison and analysis. For example, without limitation, bin capacities, ranging from 100 cm³ to 10,000 cm³, may be scaled between 0 and 1, and medication volumes, ranging from 1 cm³ to 500 cm³, may be similarly scaled between 0 and 1.

In Z-score normalization, for each value (X) in the dataset, the mean (μ) and standard deviation (σ) are calculated. For each value (X) in the dataset, the Z-Score normalization formula is applied according to:

$$Z = \frac{X - μ}{σ}$$

to adjust each value such that the resulting dataset has a mean of zero and a standard deviation of one. The original values X are replaced with the normalized values Z, resulting in a normalized dataset.

Once the data is cleaned and scaled, further transformations may be applied to make the data suitable for use in ML models. The transformations may include, for example, without limitation, categorical encoding, interaction features, and log transformations. Categorical encoding may include encoding categorical features (e.g., temperature sensitivity, security levels, etc.) into numerical values such that the machine learning models may process the categorical features. Categorical encoding may be achieved via, for example, without limitation, one-hot encoding for non-binary categories, or label encoding for binary categories. Interaction features may include creation of interaction terms to capture relationships between features. For example, without limitation, an interaction between temperature sensitivity and proximity to cooling units may be crucial for ensuring that temperature-sensitive medications are stored in bins adjacent to cooling units. An exemplary interaction feature may thus be:

Interaction=Temperature Sensitivity×Proximity to Cooling

Log transformations may be used for skewed data distributions (e.g., medication access frequency) to normalize the data and reduce an impact of extreme values.

At step 506, feature engineering of the pre-processed data is performed. Feature engineering may include domain-specific feature creation, wherein a set of domain-specific features may be created based on, for example, without limitation, expert knowledge, and the unique constraints of a specific problem. Such features may capture key attributes of medications and cabinets that may influence where medications should be placed for optimal storage, such as bin capacity utilization, a controlled substance indicator, a hazardous material flag, an ease of access score, a temperature sensitivity and cooling requirement, etc.

Bin capacity utilization may be a calculated ration of a medication's volume to the available capacity of a bin, which may ensure that the system takes into consideration how much space a medication will occupy in relation to the total available space in the bin. Bin capacity utilization may be calculated according to:

$$Bin Capacity Utilization = \frac{Medication Volume}{Bin Capacity}$$

For example, a medication with a volume of 50 cm³ may be placed in a bin with a 100 cm³ capacity would result in a bin capacity utilization score of 0.5, indicating that the bin is 50% full.

The controlled substance indicator may be a binary feature indicating whether the medication is a controlled substance, which may require storage in a secure, restricted-access bin. The controlled substance indicator may have a value of 1 for controlled substances, and a value of 0 for regular medications. For example, without limitation, narcotics and other controlled substances may have a value of 1 to ensure the narcotics are placed in secure bins. The hazardous material flag may be a binary feature that identifies whether the medication is hazardous and requires special handling or isolated storage.

The hazardous material flag may have a value of 1 for hazardous medications, and a value of 0 for non-hazardous medications. For example, without limitation, chemotherapy drugs may have a hazardous flag set to 1, causing the system to store the chemotherapy drugs in isolated or specially designated bins.

The ease of access score may be a feature that quantifies how easily accessible a medication is for retrieval from its assigned location. The ease of access score may be calculated based on, for example, the bin's physical location and the medication's access frequency:

Ease of Access=Accessibility Index×Frequency of Access

Thus, frequently accessed medications stored in easily accessible bins may have a high ease of access score, which may encourage placement in more convenient locations within a medication storage cabinet.

The temperature sensitivity and cooling requirement may be a binary feature indicating whether a medication is temperature-sensitive and must be stored in a refrigerated bin. The requirement may have a value of 1 for medications that require refrigeration, and 0 for medications that do not require refrigeration. For example, vaccines and biological products may have a temperature sensitivity requirement set to 1 to ensure they are stored in bins with cooling capabilities.

Interaction features may also be determined during feature engineering. In one embodiment, a relationship between two or more features may be more important than the individual feature values. Interaction features may be used to capture complex relationships between individual features and allow the machine learning model to understand combined effects of the individual features. For example, without limitation, there may be an interaction feature between temperature sensitivity and proximity to cooling units, medication volume and bin capacity, etc. Temperature sensitivity and proximity to cooling units may be used to ensure temperature-sensitive medications are stored in areas with adequate cooling, and may be calculated according to:

Temp−Cooling interaction=Temperature Sensitivity×Proximity to Cooling Unit

If a temperature-sensitive medication is placed in a bin that is far from a cooling unit, for example, the medication would have a low interaction score, indication a potential storage issue. The medication volume and bin capacity interaction may be used to ensure that large medications are assigned to bins that can accommodate them without causing overflow. The interaction may be calculated according to:

Volume−Capacity Interaction=Medication Volume×Bin Capacity Utilization

Thus, medications with large volumes occupying a significant portion of a bin may have a high interaction score, which may guide the machine learning model to assign a storage location able to accommodate for the high volume.

Additionally, algorithms may be used that combine existing variables to create new features that capture essential aspects of the data, such as interaction terms in regression models. Interaction terms may be used to capture the combined effects of multiple medication attributes within a regression model. The combined effects may reveal relationships that are not apparent when considering each attribute individually. For example, medications may differ in size, type (e.g., liquid or solid), usage frequency, etc. Larger medications may require additional storage space or slots within a cabinet, different types of medication may require different storage conditions, and more frequently accessed medications should be more accessible. Interaction terms may be used to capture how a combination of these attributes affects an optimal configuration, where a combination of attributes does not necessarily have an additive effect on efficiency of medication storage. When considering size and type, a large liquid-type medication may have different requirements than a large tablet-type medication. When considering size and usage frequency, large, frequently used medication should be more accessible than infrequently used large medications. Interaction terms may be used within a regression equation to consider nuanced ways in which different attributes interact with each other.

Feature engineering may also include temporal and aggregated features. Medication usage patterns may vary over time and such variations may be considered when optimizing cabinet configurations. Temporal and aggregated features may be used to capture time-based patterns and summarize multiple observations over time. Temporal and aggregated features may include, for example, without limitation, average access frequency, seasonal demand variation, failure rate of storage bins, etc.

Average access frequency may be used to capture an average number of times a medication is retrieved from the cabinet within a specific time period (e.g., daily, weekly, etc.), and may be calculated according to:

$$Average Access Frequency = \frac{Total Accesses}{Time Period}$$

For example, without limitation, a medication that is retrieved 20 times over a 7-day period may have an average access frequency of approximately 2.86 retrievals per day.

Seasonal demand variation may model seasonal demand for medications, which may vary according to seasonal events (e.g., flu season, allergy season) or other recurring health events. Sinusoidal functions may be used to capture cyclic patterns in demand over the year:

$$Seasonal Demand = sin ( \frac{2 π \cdot Month}{12} ) and cos ( \frac{2 π \cdot Month}{12} )$$

For example, without limitation, flu vaccines may have a higher demand in certain months of the year, and the seasonal demand variation feature may be used to capture such cyclic trends and ensure adequate storage is allocated during peak times.

Failure rate of storage bins may aggregate historical data on the reliability of storage bins, such as their failure rates, to ensure that critical medications are not stored in unreliable bins. The failure rate may be calculated according to:

$$Failure Rate = \frac{Number of Failures}{Total Accesses}$$

Bins with a history of malfunction or failure may have a high failure rate, encouraging the system to avoid placing important medications in such bins.

As the data features may have different scales (e.g., medication volume may be measured in cubic centimeters, while access frequency may be a simple count), the data features may be normalized and/or standardized to ensure that all features contribute equally to the optimization process.

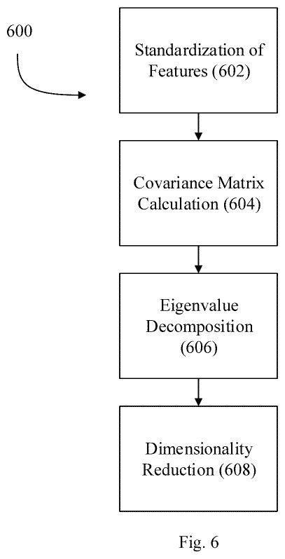

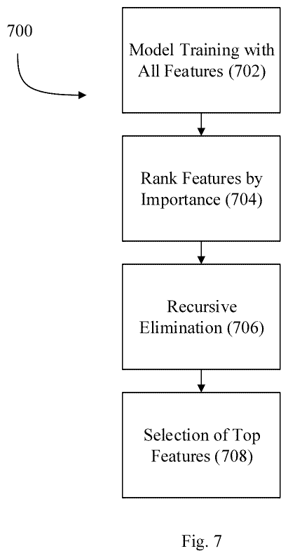

At a step 508, feature selection and dimensionality reduction may be performed, which may include, for example, without limitation, Principal Component Analysis (PCA), Recursive Feature Elimination (RFE), and Feature Importance Scoring (FIS), all of which serve to reduce the originally collected data to a manageable amount of data. PCA may be used for dimensionality reduction to improve efficiency by reducing the number of variables. By transforming a high-dimensional dataset of medication attributes (such as size, type, and usage frequency) into a smaller set of principal components, PCA identifies the most significant patterns and relationships among the input data. This reduction in dimensionality enhances the organization and accessibility of medications, streamlining inventory management and improving efficiency in healthcare environments. PCA thus enables the design of medication storage cabinets that are both space-efficient and user-friendly, ensuring quick and accurate access to essential medications. PCA is discussed in further detail below with reference to FIG. 6. RFE may be used to iteratively remove least important features based on their contribution to the model's performance. By focusing on only the most relevant features, RFE may improve the model's accuracy and efficiency. RFE is further described below with reference to FIG. 7.

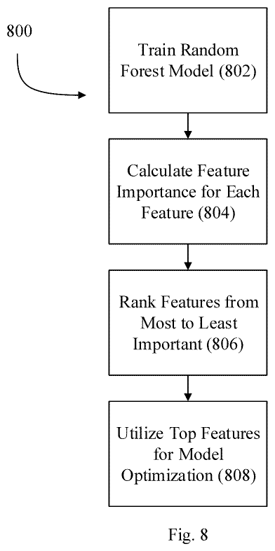

FIS may be used to identify which features have the greatest impact on model predictions. FIS may assign a score to each feature based on how much the feature contributes to reducing error in the model. FIS is further described below with reference to FIG. 8.

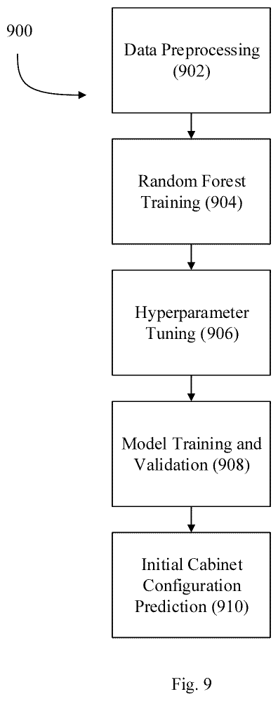

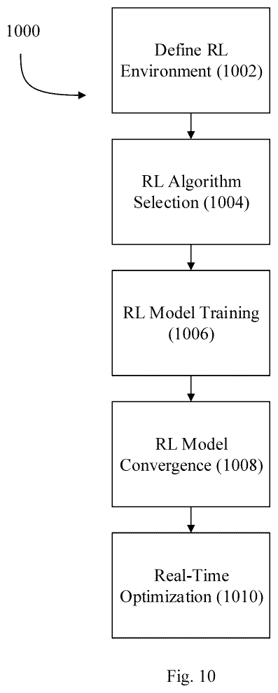

At step 510, ML model development may be performed based on the pre-processed and reduced collected data. In one embodiment, two core models may be used: a Random Forest (RF) model for initial configuration and a Reinforcement Learning (RL) model for dynamic real-time optimization. The models may work together to ensure continuous improvement in cabinet efficiency and medication storage safety. The RF model may be used for an initial configuration of the medication storage cabinet based on historical data and may leverage engineered features and perform an ensemble learning process to make robust decisions. The RF model development is further described below with reference to FIG. 9. While the RF model may provide an initial configuration, the RL model may be used to ensure continuous optimization of the medication storage cabinet by dynamically adapting to real-time feedback. The RL agent may learn optimal storage policies by interacting with the environment (i.e., the cabinet) and receiving rewards based on the success of its actions. RL model development is further described below with reference to FIG. 10.

For optimization of medication storage cabinet configurations, supervised learning models offer significant advantages in terms of accuracy and precision. Supervised learning models may be trained on labeled data, meaning that the relationships between the inputs (medication attributes) and outputs (optimal configurations) are known. This allows for precise predictions and a clear understanding of how different features impact the optimal cabinet setup. Supervised learning models also have strong predictive capabilities, making them reliable for new, unseen data. They can be customized to address specific needs, such as storage conditions or usage frequency, by selecting relevant features and appropriate algorithms. Furthermore, the performance of supervised models can be quantitatively evaluated using various metrics, ensuring continuous improvement and validation against real-world scenarios. The supervised learning models used herein may include, for example, without limitation, decision trees, random forests, Gradient Boosting Machines (GBMs), deep learning, etc. Decision trees and random forests may be used for both classification and regression tasks, providing robust solutions for predicting optimal storage configurations. Decision trees may be used to split data into branches based on feature values, creating a tree-like structure where each node represents a decision based on a feature, and each branch represents an outcome. Decision trees may be used to classify medications into different storage categories or to predict specific storage locations based on their attributes. For classification tasks, decision trees may be used to categorize medications based on features such as size, type, usage frequency, and storage requirements. For example, a decision tree may classify medications as needing refrigeration or not, based on attributes like temperature sensitivity and storage guidelines. The tree structure helps in visualizing the decision-making process, making it easier to understand and interpret the model's predictions. For regression tasks, decision trees can predict numerical outcomes, such as the optimal shelf height or the space required for each medication. By considering attributes such as medication dimensions and usage frequency, a decision tree can estimate the most efficient configuration for the cabinet, ensuring that medications are easily accessible and properly stored. Random forests build on the concept of decision trees by creating an ensemble of multiple trees to improve prediction accuracy and robustness. Each tree in a random forest is trained on a random subset of the data and features, and the final prediction is made by aggregating the predictions from all individual trees. This approach helps to mitigate the overfitting issue often encountered with single decision trees and enhances the model's generalization capabilities. For classification, random forests can categorize medications into various storage categories by considering multiple attributes. The ensemble approach ensures that the model captures complex interactions between features, providing more accurate and reliable classifications compared to a single decision tree. For regression tasks, random forests can predict optimal storage configurations by averaging the predictions from multiple decision trees. This ensemble method reduces the variance of the predictions and improves the overall accuracy. For example, random forests can predict the optimal shelf layout or the space allocation for each medication, considering various attributes and their interactions.

A GBM may be used to sequentially build an ensemble of decision trees, creating a strong predictive model. This approach is particularly effective for optimizing medication cabinet configurations by leveraging multiple trees to enhance accuracy and robustness. In the present embodiment, the GBM operates by adding decision trees in sequence, with each new tree focusing on correcting errors made by the previous trees. Guided by a gradient descent optimization algorithm, the GBM minimizes a loss function, ensuring iterative improvement of the model. This method effectively captures complex relationships between medication attributes and optimal storage solutions. To determine the optimal configuration of a medication cabinet, the GBM may process various attributes such as medication size, type (e.g., tablet, liquid), usage frequency, and specific storage requirements (e.g., refrigeration, light sensitivity). The GBM is trained using the gathered and processed data from steps 506-508. During training, the model learns to associate medication attributes with optimal storage configurations by minimizing prediction errors through the iterative addition of decision trees. Model validation follows, where the performance of the GBM is evaluated using a separate validation dataset to ensure it generalizes well to new, unseen data. This step helps tune hyperparameters, such as learning rate and number of trees, to achieve the best performance. Once trained and validated, the GBM may be used to predict the optimal configuration for the medication cabinet. This includes determining the best placement for each medication, taking into account factors like accessibility, storage requirements, and space optimization.

Deep learning may be used for determining the optimal configuration of a medication cabinet by recognizing complex patterns and relationships within data. Herein, deep learning models nay include multiple layers of neurons that process input data through various transformations. Each layer extracts higher-level features from the raw data, enabling the model to learn complex patterns and make accurate predictions. Deep learning may be used to handle a vast array of attributes, including medication size, type (e.g., tablet, liquid), usage frequency, and specific storage requirements (e.g., refrigeration, light sensitivity). Designing the architecture of the neural network is a crucial step. This involves deciding on the number of layers, the number of neurons in each layer, and the types of layers (e.g., convolutional layers for spatial data, recurrent layers for sequential data). The architecture is tailored to capture the complex relationships between medication attributes and optimal storage configurations. The neural network is trained on the preprocessed dataset. The training process involves feeding the data through the network and adjusting the weights and biases of the neurons to minimize the loss function. This iterative process allows the model to learn from the data and improve its predictions. Techniques like backpropagation and gradient descent are employed to optimize the model. To ensure the model generalizes well to new data, it is validated using a separate validation dataset. This step involves evaluating the model's performance and tuning hyperparameters, such as learning rate, batch size, and the number of epochs. Techniques like cross-validation and grid search can be used for hyperparameter optimization. Once trained and validated, the deep learning model can predict the optimal configuration for the medication cabinet. These predictions include determining the best placement for each medication, considering factors like accessibility, storage requirements, and space optimization. The model can be deployed in a healthcare facility to assist in real-time decision-making for medication storage.

Unsupervised learning models do not require labeled data, making them easier and cheaper to implement as there is no need for extensive data labeling. These models can identify hidden patterns and relationships within the data that may not be apparent with supervised learning, potentially leading to unexpected insights that improve the overall cabinet configuration. Unsupervised learning is flexible and can adapt to various data types and structures, making it versatile for different aspects of medication attributes and storage conditions. Unsupervised learning models may be particularly useful for initial data exploration, providing a preliminary understanding of the data structure, and may include, for example, without limitation, clustering algorithms such as K-means or hierarchical clustering.

K-Means Clustering is an unsupervised learning algorithm that partitions data into k distinct clusters based on feature similarity. This technique may be used to determine the optimal configuration of a medication cabinet by grouping medications with similar attributes together, thus enhancing storage efficiency and accessibility. K-Means Clustering operates by initializing k cluster centroids and iteratively refining their positions to minimize the variance within each cluster. Each medication is assigned to the nearest centroid, and the centroids are then adjusted based on the mean of the assigned points. This process repeats until the centroids stabilize, resulting in k distinct clusters that represent groups of medications with similar characteristics. K-Means Clustering can handle various medication attributes such as size, type (e.g., tablet, liquid), usage frequency, and storage requirements (e.g., refrigeration, light sensitivity). The process utilizes the collected and processed data, where detailed information on medication attributes is gathered. This dataset forms the basis for clustering. Once the clusters are formed, each cluster represents a group of medications with similar attributes. This clustering information can be used to optimize the medication cabinet configuration. For example, medications within the same cluster can be stored together, making it easier to access similar items and ensuring that storage conditions are consistently met. K-Means Clustering is computationally efficient, making it suitable for large datasets with many features. The algorithm is relatively simple to implement and understand, providing clear clusters that group similar medications together. K-Means Clustering can effectively handle numerical data and is flexible enough to adapt to different types of medication attributes.

Hierarchical Clustering is used to build a hierarchy of clusters by either merging smaller clusters into larger ones (agglomerative) or splitting larger clusters into smaller ones (divisive). This technique may be used to determine the optimal configuration of a medication cabinet by organizing medications into a hierarchy based on their attributes, thereby enhancing storage efficiency and accessibility. Hierarchical Clustering operates by creating a dendrogram, a tree-like structure that represents the nested grouping of medications and the hierarchy of clusters. In agglomerative clustering, each medication starts as its own cluster, and pairs of clusters are merged iteratively based on their similarity until a single cluster encompassing all medications is formed. In divisive clustering, the process starts with one cluster containing all medications, which is then recursively split into smaller clusters. In the context of medication cabinet configuration, Hierarchical Clustering can handle various medication attributes such as size, type (e.g., tablet, liquid), usage frequency, and storage requirements (e.g., refrigeration, light sensitivity). With the prepared dataset, the Hierarchical Clustering algorithm is applied. The algorithm calculates the similarity between all pairs of clusters and merges the most similar ones. This process is repeated iteratively, updating the dendrogram at each step, until a single cluster is formed that contains all medications. The resulting dendrogram provides a visual representation of the hierarchical structure of the clusters. By cutting the dendrogram at a specific level, the desired number of clusters can be obtained. Each cluster represents a group of medications with similar attributes. This hierarchical clustering information can be used to optimize the medication cabinet configuration. Medications within the same cluster can be stored together, making it easier to access similar items and ensuring that storage conditions are consistently met. The hierarchical structure also allows for organizing medications at different levels of granularity, from broad categories to specific groupings. Hierarchical Clustering offers several advantages for optimizing medication storage cabinet configurations. It does not require the number of clusters to be specified in advance, providing flexibility in discovering the natural grouping of medications. The dendrogram provides a comprehensive view of the data's structure, allowing for easy interpretation of the relationships between medications. Hierarchical Clustering can handle various types of data and similarity measures, making it adaptable to different medication attributes.

In one embodiment, once the AI and/or ML models are trained, the AI and/or ML models may be deployed for real-time inference and optimization. This process involves using the trained models to create an initial optimized medication storage cabinet configuration, make decisions about how to place medications in the cabinet and how to adapt to changing environmental conditions. When a new batch of medications arrives, the random forest model may be used to predict an initial placement for the medications based on the trained model and the current state of the cabinet (e.g., available bin space, temperature zones, security needs, etc.). The system may continuously monitor real-time data from sensors within the cabinet, tracking parameters such as bin temperature, bin occupancy, and environmental conditions (e.g., failures in cooling units, power outages, etc.). The RL agent may then be used to utilize the real-time feedback in dynamically adjusting the medication placement. For example, if a cooling unit fails, the RL model may move temperature-sensitive medications to another bin with appropriate cooling. The RL model may operate in a feedback loop, where the RL model continuously monitors the cabinet environment, takes actions, and learns from new data. This allows the system to remain optimized over time, even as conditions change.

At step 512, after the AI and/or ML models for medication storage cabinet optimization are trained and deployed, the models may be evaluated for their performance to validate their effectiveness in real-world conditions. The models may be evaluated based on a range of performance metrics, validation techniques, and robustness checks to ensure that the models perform reliably, both during training and in real-time operation.

Random forest model metrics may include accuracy, Mean Square Error (MSE), Precision and Recall, and a confusion matrix. The accuracy metric may be a measurement of how often the model correctly predicts the optimal bin for each medication. Accuracy may be calculated according to:

$$Accuracy = \frac{N umber of Correct Predictions}{Total Predictions}$$

For example, if the system correctly assigns 95 out of 100 medications to the appropriate bins, the system may have an accuracy of 95%.

The Mean Squared Error (MSE) metric may be used to evaluate an average squared difference between the predicted and actual bin assignments, and may be used if continuous predictions are made. The MSE may be calculated according to:

$$M S E = \frac{1}{n} {\sum }_{i = 1}^{n} {( {y}_{i} - {\hat{y}}_{i} )}^{2}$$

A lower MSE may indicate that the model's predictions are closer to the true placements, minimizing errors in medication storage.

The precision metric may be a proportion of true positive predictions among all positive predictions (i.e., correctly identifying the correct bins for critical medications such as controlled substances or hazardous materials. Precision may be calculated according to:

$$Precision = \frac{True Positives}{True Positives + False Positives}$$

The recall metric may be a proportion of true positives identified among all actual positive cases (i.e., how well the model captures all medications requiring special storage conditions). Recall may be calculated according to:

$$Recall = \frac{True Positives}{True P ositives + False Negatives}$$

The F1 score metric may be a harmonic mean of precision and recall, and may be used to balance precision and recall. The F1 score may be calculated according to:

$$F 1 Score = 2 \times \frac{P r e c i s i o n \times Recall}{Precision + Recall}$$

A confusion matrix may provide a detailed breakdown of how well the model is classifying medications, particularly in situations where it must distinguish between categories such as temperature-sensitive and non-temperature-sensitive medications.

RL model metrics may include cumulative reward, time to convergence, policy stability, and action efficiency. The cumulative reward metric may measure the total reward accumulated by the RL agent over a series of actions. The higher the cumulative reward, the better the RL model is at optimizing the medication storage cabinet configuration. Cumulative reward may be calculated according to:

$$R = {\sum }_{t = 0}^{T} {r}_{t}$$

A high cumulative reward may indicate that the RL model consistently places medications in optimal bins, minimizing retrieval times and avoiding storage issues.

The time to convergence metric may measure how quickly the RL model converges to an optimal policy for cabinet reconfiguration. A faster convergence time may indicate that the model is learning an optimal configuration efficiently and can respond to changing conditions in real time.

The policy stability metric may measure how stable the learned policy is over time. If the RL model's policy frequently changes without significant improvements, it may indicate instability in the training process. A stable policy may ensure that the model's decisions are reliable and consistent when managing cabinet configurations.

The action efficiency metric may evaluate how efficiently the RL model takes actions that lead to an optimal cabinet configuration, minimizing the number of unnecessary reconfigurations. If the RL agent consistently places medications in their ideal bins with minimal movements, the model's action efficiency is high.

Model robustness of the models may be critical to maintaining reliable performance in real-workd scenarios. Validation techniques may be used to ensure that the models generalize well and are not overfitting the training data. Validation techniques may include, for example, without limitation, cross-validation, holdout validation, sensitivity analysis, and stress testing.

Cross-validation may be k-Fold cross validation, wherein the dataset is divided into k equal subsets (folds). The model may be trained on k−1 folds and tested on the remaining fold. This process may be repeated k times, and the performance metrics may be averaged to provide a more generalized evaluation of the model's performance. k-fold cross-validation accuracy may be calculated according to:

$$Average accuracy = \frac{1}{k} {\sum }_{i = 1}^{k} {Accuracy}_{i}$$

For example, with k=5, the dataset may be split into 5 folds, and the model may be trained 5 times on different combinations of 4 folds while being validated on the remaining fold.

Holdout validation may be a training-test split, wherein the dataset is split into two sets: a training set used to train the model and a test set used to evaluate the model's generalization performance. For example, a typical split might be 80% training and 20% testing. The model's performance on the test set may provide an unbiased estimate of how well the model will perform on unseen data.

Sensitivity analysis may be used to evaluate the model under different conditions, such as varying medication access frequency, fluctuating environmental conditions (e.g., temperature changes), or emergency scenarios where specific medications are accessed more frequently. Sensitivity analysis may be used to ensure that the model remains robust, even when operating outside typical conditions, adapting effectively to abnormal situations.

Stress testing may be used for edge cases to test the system under extreme conditions, such as overloading the cabinet with medications or simulating multiple bin failures. This ensures the system's resilience and ability to maintain performance under high-stress scenarios. For example, testing how the model reallocates medications when several temperature-sensitive medications need to be stored in a cabinet with only a few functional cooling units.

The one or more AI or ML models may be evaluated depending on the specific task performed (classification, regression, etc.). Model evaluation is a crucial step in determining the effectiveness and reliability of models used for optimizing medication cabinet configurations. Depending on the specific task, whether it involves classification or regression, different metrics are employed to evaluate the performance of the models.

For classification tasks, where the goal is to categorize medications based on their attributes (e.g., storage requirements, type), appropriate evaluation metrics include accuracy, precision, recall, and F1 score. Accuracy measures the proportion of correctly predicted categories out of the total predictions made by the model. It provides a general sense of the model's performance but can be misleading in cases of imbalanced datasets where some categories are more frequent than others. Precision is the ratio of true positive predictions to the sum of true positive and false positive predictions. It indicates how many of the predicted categories are actually correct, making it useful for understanding the model's performance in scenarios where false positives are costly. Recall is the ratio of true positive predictions to the sum of true positive and false negative predictions. It measures the model's ability to correctly identify all relevant categories, making it crucial in scenarios where missing a category (false negative) has significant consequences. F1 Score is the harmonic mean of precision and recall, providing a single metric that balances both aspects. It is particularly useful when dealing with imbalanced datasets, offering a more comprehensive view of the model's performance. To evaluate a classification model, a confusion matrix is often used to visualize the performance across different categories. By analyzing the true positives, false positives, true negatives, and false negatives, one can calculate the aforementioned metrics and gain insights into the strengths and weaknesses of the model.

For regression tasks, where the goal is to predict numerical outcomes such as optimal shelf height or space allocation, appropriate evaluation metrics include Mean Squared Error (MSE), Root Mean Squared Error (RMSE), and Mean Absolute Error (MAE). MSE measures the average of the squared differences between the predicted and actual values. It penalizes larger errors more significantly, making it sensitive to outliers. MSE provides a sense of the overall prediction error and is useful for comparing different models. RMSE is the square root of MSE, bringing the error metric back to the original scale of the data. RMSE is easier to interpret compared to MSE and provides a direct indication of the model's prediction accuracy in the units of the target variable. MAE measures the average of the absolute differences between the predicted and actual values. It provides a straightforward measure of prediction accuracy, with equal weight given to all errors. MAE is less sensitive to outliers compared to MSE and RMSE. To evaluate a regression model, these metrics are calculated on a validation dataset that was not used during model training. By comparing the MSE, RMSE, and MAE, one can assess the model's prediction accuracy and identify areas for improvement.

By systematically evaluating the models using these metrics, effectiveness and reliability for optimizing medication cabinet configurations of the one or more models may be determined. This allows for continuous improvement and refinement of the models, ultimately contributing to better organization, accessibility, and overall efficiency.

The one or more AI or ML models may be monitored, evaluated, and adjusted as needed. As medication storage requirements change over time, the one or more models may be continuously updated with new data to ensure ideal storage solutions. This process involves the use of algorithms such as online gradient descent and adaptive learning rate techniques, which enable models to adapt to new data in real time.

Online gradient descent is a variant of the gradient descent algorithm designed to update model parameters incrementally as each new data point arrives. Instead of retraining the model on the entire dataset, online gradient descent makes small adjustments based on individual data points. This approach allows for continuous learning and adaptation, ensuring that the model remains up-to-date with the latest data trends. As new medication data (e.g., new types of medications, changes in usage frequency) is collected, online gradient descent can be employed to update the model's parameters. This ensures that the model's predictions remain accurate and relevant, improving its ability to suggest optimal storage configurations in response to changing conditions. Online gradient descent is particularly advantageous in scenarios where data arrives sequentially, such as in a healthcare facility continuously updating its medication inventory. It ensures that the model remains current without the need for expensive and time-consuming batch retraining. This method also allows the model to respond quickly to changes in the data, such as the introduction of new medications or changes in storage requirements, maintaining high performance and relevance. By incrementally updating the model with each new data point, online gradient descent reduces memory and computational resource requirements, making it suitable for real-time applications and environments with limited resources.

Adaptive learning rate techniques adjust the learning rate dynamically based on the performance of gradient updates during training. Implementing these techniques involves algorithms like AdaGrad, RMSprop, and Adam, which automatically modify the learning rate to improve convergence. AdaGrad adapts the learning rate for each parameter based on the historical gradients, allowing larger updates for infrequent parameters and smaller updates for frequent ones. RMSprop modifies AdaGrad by considering only recent gradients, preventing the learning rate from decaying too quickly. Adam combines the benefits of both AdaGrad and RMSprop by using estimates of first and second moments of the gradients to adapt the learning rate. These adaptive methods help models efficiently learn from new data, especially in dynamic environments, ensuring faster convergence and better performance by preventing issues like overshooting or getting stuck in local minima. By employing adaptive learning rate methods, the model can maintain high performance as it processes new data. This is particularly important in a dynamic environment where medication attributes and storage requirements may frequently change. Adaptive learning rate techniques help the model to quickly adjust to new information, enhancing its ability to provide accurate and timely predictions.

RL is a powerful approach for training systems to make decisions in dynamic environments through trial and error. In the context of medication cabinet configuration, RL can be used to optimize storage configurations by learning the best actions to take based on feedback from the environment. Algorithms such as Q-learning and Deep Q Networks (DQNs) are particularly effective for this purpose.

Q-learning is an RL algorithm that learns the value of taking a particular action in a given state, known as the Q-value. By exploring different actions and receiving feedback in the form of rewards or penalties, the algorithm iteratively updates the Q-values to converge on an optimal policy. Q-learning may be used to learn the best storage configurations by experimenting with different setups and observing the resulting efficiency and accessibility.

Deep Q Networks combine Q-learning with deep neural networks to handle high-dimensional state spaces. DQNs use a neural network to approximate the Q-values, enabling the algorithm to learn complex relationships between states and actions. This approach is particularly useful for optimizing medication cabinet configurations where the state space may include various attributes of medications and their storage requirements.

In a practical implementation, a RL system may be deployed to continuously adjust the medication cabinet configuration. The system would interact with the environment by experimenting with different storage setups and receiving feedback on factors such as retrieval time, accessibility, and storage conditions. Through this trial-and-error process, the RL algorithm would learn to identify the most efficient and effective storage configurations.

FIG. 6 depicts an illustrative example of a flow chart of a method 600 for performing Principal Component Analysis (PCA) according to an embodiment of the present disclosure. At step 602 of method 600, the collected data may be sorted into features (e.g., bin capacity, medication volume, temperature sensitivity, security level, hazardous status, access frequency, etc.) and standardized to ensure consistency and comparability. This involves adjusting the features so that each value or attribute of the dataset has a mean of zero and a standard deviation of one. Standardization is crucial for accurate analysis, as it normalizes the scale of different attributes, eliminating bias due to varying units or measurement scales and ensuring that features with larger scales (e.g., bin capacity) do not dominate the principal components.

At step 604, a covariance matrix is calculated based on the standardized features. This matrix captures the relationships between the different medication and/or cabinet features (e.g., bin capacity, medication volume, temperature sensitivity, etc.), indicating how changes in one attribute correspond to changes in another. The covariance matrix is essential for identifying the underlying structure of the data.

At step 606, from the covariance matrix, the system may calculate eigenvalues and eigenvectors. The covariance matrix may be decomposed into eigenvectors, representing the directions of the principal features, and eigenvalues, representing the amount of variance explained by each principal component. This step is fundamental in determining the principal components that will be used for dimensionality reduction.

At step 608, dimensionality reduction may be performed. The top k principal components explaining a majority of the variance (e.g., 95%) are selected. Dimensionality reduction may be used to reduce the number of features while retaining key information necessary for the model to function accurately. For example, without limitation, a first principal component (PC1) may capture a relationship between bin capacity and medication volume, emphasizing space utilization, while a second principal component (PC2) may capture a relationship between temperature sensitivity and proximity to cooling units, focusing on environmental constraints. In one embodiment, a dataset with 6 original features (bin capacity, medication volume, temperature sensitivity, security level, hazardous status, access frequency) may be reduced to 2 or 3 principal components that capture the most important relationships, such as space utilization and cooling requirements.

FIG. 7 depicts an illustrative example of a flow chart of a method 700 for performing Recursive Feature Elimination (RFE) according to an embodiment of the present disclosure. At step 702 of method 700, a machine learning model may be selected and trained for evaluating feature importance. The machine learning model may be, for example, without limitation, linear regression, support vector machine (SMV), decision tree, etc. In the present embodiment, a Random Forest (RF) may be used for RFE. The selected machine learning model may be trained using the processed medication cabinet configuration features based on importance to cabinet configuration. The machine learning model may then rank the features, where the ranking is determined by how much each feature contributes to the efficiency of the medication cabinet configuration. Feature importance scores may be calculated based on an impact of each feature to the model's predictions. At a step 704, the features may be ranked by importance scores. Features that contribute the least to model accuracy would thus be candidates for removal. At step 706, the least important feature(s) may be recursively eliminated based on the determined ranking, thus reducing the dataset and drawing focus to the most critical features for optimizing the to-be-determined cabinet configuration. The model may be retrained based on the remaining features. The removal process may be performed iteratively, removing one feature at a time until an optimal number of features is reached. Re-fitting may be performed to updated the model with the reduced feature set an accurately determine each features' importance. At step 708, the top features may be selected. Once the model's performance begins to degrade (indicating that key features are being removed) the top n features that maximize performance may be selected for final training. For example, without limitation, RFE may identify that medication access frequency and temperature sensitivity are the most critical features for cabinet configuration, while less important features like hazardous status may be eliminated.

FIG. 8 depicts an illustrative example of a flow chart of a method 800 for performing feature importance scoring according to an embodiment of the present disclosure. For a RF model, feature importance may be calculated by measuring how much a particular feature improves the purity of the splits in decision trees. The more a feature is used to make decisions that reduce error, the higher the feature's importance score. After calculating the feature importance scores, features may be ranked from most important to least important. This ranking may be used in identifying which features should be prioritized for further model development. At step 802 of method 800, the RF model may be trained with features. The model may be configured to learn the relationships between medication features and their corresponding efficiency within a cabinet configuration. At step 804, feature importance scores may be calculated for each feature. Feature importance scores may indicate a contribution of each feature to the model's predictions or the overall configuration efficiency. At step 806, the features may be ranked according to their feature importance scores, where higher scores have a greater influence in the efficiency of a cabinet configuration. At step 808, the top-ranked features may be selected, wherein the top-ranked features will be prioritized in the design and organization of the medication cabinet to maximize accessibility, efficiency, and compliance with storage requirements.

FIG. 9 depicts an illustrative example of a flow chart for a method 900 for performing RF model development according to an embodiment of the present disclosure. At step 902 of method 900, features may be input into the model. The features may have been or may be subject to preprocessing, standardizing, being transformed, and dimensionality reduction techniques (PCA and/or RFE) may have been applied such that the RF model may more effectively process the input features.

At step 904, the RF model may be trained using the input features. The RF model may utilize ensemble learning. The RF model may be composed of multiple decision trees, each trained on a different subset of the input features. Each decision tree may be used to make an independent prediction, and the final prediction may be obtained by averaging the outputs of al the trees (for regression) or using majority voting (for classification). Exemplary hyperparameters of the random forest may be number of trees (estimators), maximum depth of each tree, minimum samples required for a split, etc.

At step 906, hyperparameter tuning may be used for finding an optimal configuration of the RF model. Techniques such as grid search or random search may be used to test various combinations of hyperparameters, and cross-validation may be applied to ensure generalization to new data.

At a step 908, a best RF model may be selected based on various performance metrics (e.g., accuracy, precision, recall, mean squared error (MSE), etc.). Cross-validation may be used to ensure that the model does not overfit and generalizes well to unseen data.

At a step 910, the trained model may be used to generate or predict an optimal initial configuration of medications in the cabinet, taking into consideration key factors such as bin size, temperature sensitivity, medication demand, security access, etc.

The RF model may be trained using a training dataset including features related to medication characteristics (e.g., volume, temperature sensitivity, security level, etc.) and cabinet constraints (e.g., bin capacity, temperature zones, etc.). The data may be preprocessed, scaled, and transformed as described above. The random forest model may be trained using an ensemble of decision trees, where each tree is built by randomly selecting subsets of the training data and features. This ensures that the model captures different aspects of the data and reduces the risk of overfitting. To ensure that the model generalizes well, k-fold cross-validation may be applied. The training data may be split into k subsets, and the model may be trained on k−1 subsets while the remaining subset is used for validation. This process may be repeated k times, and the final model performance may be averaged across all iterations. Grid Search or Random search may be used to find an optimal combination of hyperparameters, including, for example, without limitation, a number of trees in the forest, maximum depth of the trees, minimum samples required to split a node, etc. The best performing hyperparameters may be selected based on model accuracy and error metrics. The finally trained model may be evaluated using metrics such as, without limitation, accuracy (i.e., how often the model predicts the correct bin configuration), Mean Squared Error (MSE) (i.e., the average squared difference between predicted and actual medication placements), precision and recall (i.e., how well the model balances false positives and false negatives when placing medications in bins with special requirements), etc.

FIG. 10 depicts an illustrative example of a flow chart of a method 1000 for RL model development according to an embodiment of the present disclosure. At step 1002 of method 1000, a reinforcement environment may be defined. The reinforcement environment may include a state space, action space, and reward function. The state space may represent a current configuration of the cabinet, including, for example, without limitation, medication placement, bin occupancy, temperature status, and security level. The action space may represent possible actions an agent can take, but not limited to, moving a medication to a different bin, adjusting temperature, reallocating space, etc. The agent may utilize a reward function that rewards the agent for actions that improve cabinet efficiency (e.g., reducing retrieval time, ensuring proper temperature storage, etc.) and penalize suboptimal actions (e.g., storing temperature-sensitive medication in a non-cooled bin).

At step 1004, an RL algorithm may be selected. For example, Q-Learning or Deep Q-Networks (DQN) may be used to learn the optimal policies for dynamic cabinet reconfiguration. This may use a value-based approach to estimate the quality of each action in a given state. The Q-learning equation may be the following:

Q(s,a)←Q(s,a)+α(r+γmax_{α}Q(s′,a′)−Q(s,a))
where Q(s,a) is the expected reward for taking action a in state s;
α is the learning rate;
r is the reward for the current action;
γ is the discount factor; and
s′ is the next state after taking action a.

At step 1006, the RL Model may be trained by interacting with a simulated cabinet environment, performing actions, and receiving rewards or penalties based on the results. Over time, the RL agent may learn which actions lead to the most optimal cabinet configurations.

At step 1008, the RL model may converge when the Q-values stabilize, indication that the agent has learned an optimal or near-optimal policy for configuring the medication storage cabinet.

At step 1010, once the RL model is deployed, the RL model may continuously monitor real-time feedback from the cabinet (e.g., temperature changes, bin failures, etc.) and dynamically adjust the configuration as necessary.

The RL training process may begin with defining state and action spaces, where the state space may represent the current configuration of the cabinet, including the location of medications, bin statuses, environmental conditions, etc., and the action space represents the set of possible actions that the agent can take, such as moving medications to different bins, adjusting temperatures, reconfiguring storage locations, etc. The reward function may then be defined to assign positive rewards for optimal actions (e.g., placing temperature-sensitive medications in refrigerated bins) and penalties for suboptimal actions (e.g., placing medications in overfilled or undercooled bins. The Q-learning or Deep Q-Network (DQN) algorthim may then be used to train the RL model. The agent may interact with the environment by taking actions and receiving feedback (rewards or penalties) based on the results of those actions. The RL agent may balance exploration (trying new actions to discover better solutions) and exploitations (choosing known actions with high rewards). For example, an epsilon-greedy strategy may be used, where the agent occasionally explores new actions but mostly exploits known good actions as it learns. The RL model may converge when the Q-values stabilize, indicating that the agent has learned an optimal or near-optimal policy for managing the medication storage cabinet. Once convergence is reached, the learned policy is deployed for real-time optimization.

A combination of the Random Forest and RL models may be used to combine the strengths of each model. The Random Forest model may be used to generate an initial configuration when new medications or bin changes are introduced. This may provide a robust starting point based on historical data and predefined features. After the initial configuration, the RL model may continuously adjust the cabinet layout in response to a real-time data (e.g., medication access patterns, environmental changes, etc.). The RL model may adapt to fluctuations in medication demand, temperature problems, cabinet failures, etc., ensuring that the configuration remains optimized under changing conditions.

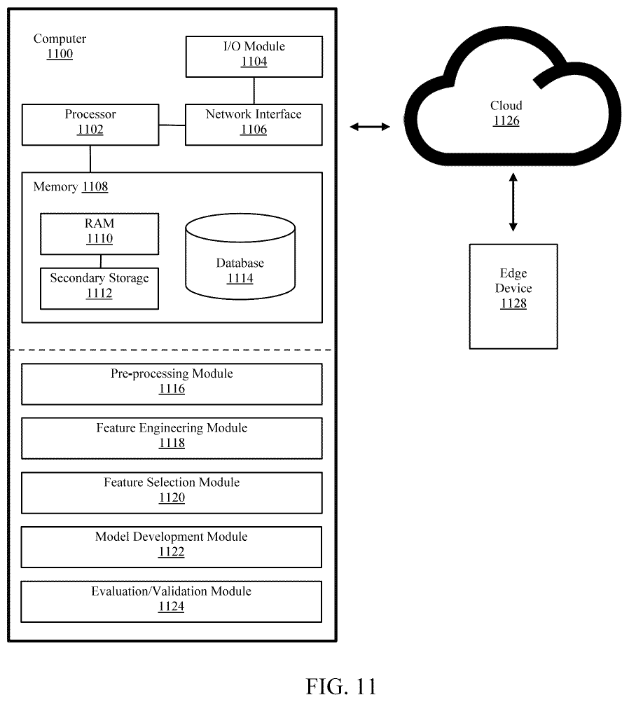

FIG. 11 depicts an illustrative example of a system for determining a medication storage cabinet configuration according to an embodiment of the present disclosure. System 1100 is configured to take requests from customers 1102, process the requests, and provide customers 1102 with a medication storage cabinet organization implementation, or an update to a medication storage cabinet organization system. Customer requests for cabinet configurations 1104 are input by providing detailed information 1106 about their medication inventory and stock area. Detailed information 1106 may include specifics such as the types and quantities of medications, their physical dimensions, usage frequencies, and any special storage requirements like refrigeration or light sensitivity. Additionally, detailed information 1106 may include information about the stock area, such as available shelf space, accessibility constraints, and organizational preferences. This comprehensive data enables the system to tailor cabinet configurations that optimize storage efficiency, accessibility, and compliance with storage requirements, ensuring that the layout meets the unique needs of each customer. Detailed information 1106 may be input into processing module 1108 for data integration 1110, where detailed information 1106 may undergo data preprocessing, feature engineering, etc. The processed data may be coupled with historical data from datastore 1112 and utilized by trained models 1114 to generate cabinet configurations 1116. Trained models 1114 may include optimization algorithms such as, but not limited to, Linear Programming (LP), Genetic Algorithms (GA), Particle Swarm Optimization (PSO), etc. for spatial and inventory optimization. Linear Programming (LP) is a technique used for optimizing a linear objective function, subject to linear equality and inequality constraints. In the context of medication storage cabinets, LP may be utilized to determine the most efficient arrangement of medications by maximizing space utilization and ensuring compliance with storage requirements, while minimizing retrieval time and cost. Genetic Algorithms (GA) are inspired by the process of natural selection and are particularly effective for solving complex optimization problems with large search spaces. GA operates by evolving a population of potential solutions over successive generations, using operations such as selection, crossover, and mutation. For medication storage cabinet optimization, GA, may be used to explore various configuration possibilities, iteratively improving the layout to find the most optimal arrangement that meets all specified constraints and requirements. Particle Swarm Optimization (PSO) is a population-based optimization technique inspired by the social behavior of birds flocking or fish schooling. PSO involves a group of particles (potential solutions) that move through the solution space, adjusting their positions based on their own experience and the experience of neighboring particles. This approach allows PSO to effectively search for optimal cabinet configurations by balancing exploration and exploitation of the search space, leading to efficient and effective optimization of spatial arrangements and inventory management.

Trained models 1118 may then be used for medication assignment suggestions 1120. Trained models 1118 may include unsupervised learning algorithms, such as K-means clustering or hierarchical clustering as described above to group medications based on characteristics and storage requirements, and supervised learning algorithms such as random forests to generate optimal medication assignment suggestions based on the generated cabinet configurations.

Customers 1102 may also request medication assignment optimization 1122 where a cabinet configuration and medication assignment have been previously determined. Medication assignment optimization 1122 may be determined on a continuously, according to a predefined schedule, or as a one-time basis depending on the needs of customers 1102. Medication assignment optimization request 1122 may be processed to retrieve data about new medications and the one or more stock areas to which the new medications should be assigned. The new medication data may be input into trained models 1118 to determine medication assignment suggestions, and be parsed into optimization requests 1126 for medication assignment optimization module 1124.

Medication assignment optimization module 1124 may be a trained model utilizing Decision Support System (DSS) methodologies in analyzing and generating recommendations for reassignment or adjustments in storage configurations of medication storage cabinets. These systems integrate data analysis, sophisticated algorithms, and user-friendly interfaces to assist healthcare professionals in making informed decisions regarding the optimal arrangement of medications. Using advanced analytical tools, the DSS processes the collected data to identify patterns, inefficiencies, and opportunities for improvement. Techniques such as descriptive analytics, predictive modeling, and optimization algorithms are employed to understand the current state of the storage configuration and predict the impact of potential changes. Based on the analysis, the DSS generates actionable recommendations for reassigning or adjusting storage configurations. These recommendations are tailored to meet the specific goals and constraints of the customer.

Optimization requests 1124 may be dependent on specific needs of customers 1102. For example, customers 1102 may prioritize certain aspects of a medication storage cabinet organization system over others, such as placing an emphasis on efficient space utilization to maximize storage capacity over minimizing retrieval time of medication. Such individual optimization requests may be input into trained model 1128 to generate automated optimization proposals 1130.

Trained model 1128 may be a constraint satisfaction problem (CSP) solver to handle customer optimization requests for medication cabinet configurations by ensuring that all specified constraints are met during the optimization process. CSP involves finding solutions to problems characterized by a set of variables, each with a domain of possible values, and a set of constraints that restrict the combinations of values that the variables can take. Variables may be defined, where the variables represent the different medications and their storage locations. Each variable may have a domain representing the possible positions within the cabinet where the medication can be stored. Constraints may then be established as the rules or conditions that must be satisfied for a valid configuration. For a medication cabinet, these constraints may include: spatial constraints to ensure that medications fit within the available storage space, taking into account their dimensions, storage requirements to ensure that medications needing specific conditions (e.g., refrigeration, light protection) are stored in appropriate locations, accessibility constraints to ensure frequently used medications should be placed in easily accessible locations to minimize retrieval time. safety and compliance constraints to ensure certain medications are stored separately to prevent contamination or meet regulatory requirements, inventory management constraints to ensure optimal inventory levels are maintained and avoiding both overstocking and stockouts, etc. The CSP solver iteratively searches for a solution that satisfies all the constraints. This involves:

Backtracking: If a partial assignment of medications to storage locations leads to a conflict with the constraints, the solver backtracks to try different assignments.

Consistency Checking: Before assigning a medication to a location, the solver checks if this assignment is consistent with the constraints.

Optimization Criteria: The solver may also include optimization criteria such as minimizing retrieval time or maximizing space utilization, in addition to satisfying the constraints. Customer optimization requests are prioritized to satisfy optimization criteria.

Search Strategies: The CSP solver employs various search strategies to efficiently explore the possible configurations, including, for example, without limitation, Depth-First Search, Breadth-First Search, Heuristics, etc.

By employing a CSP solver, customers can ensure that their medication cabinet configurations are optimized according to customer-specific constraints and preferences, leading to efficient, compliant, and effective storage solutions that enhance overall operational performance.

Automated optimization proposals 1130 may be processed to generate formal suggestions for reassignments 1132. Suggestions for reassignments 1132 and medication assignment suggestions 1120 may be input into interaction and feedback module 1134, where they are presented to customers 1102 for review. Interaction and Feedback module 1134 may collect feedback 1136 from customers 1102, and the feedback may be used for further generation of medication assignment suggestions 1120 and/or suggestions for reassignments 1134, iterating until an optimal solution is generated that meets the needs of customers 1102. Feedback may also be used in training the models used herein, where interaction and feedback module 1134 may perform model refinement and updating 1138.

Once customer 1102 accepts the newly generated assignment or reassignment, system 1100 may perform the step of syncing assignments 1140 with one or more edge devices (i.e., cabinets) 1142. The assignments may be transmitted to cabinets 1142 for implementation. System 1100 may also be provided with live updates from edge devices 1142 for further processing and potential reassignment.

Use of cabinet 1144 may involve several operations such as, but not limited to, performing medication assignment 1146, adding stock and restocking 1148, and conducting transactions 1150. Once new assignments are generated, the new assignments may be used to update existing assignments 1150, which may include relocating medication, removing medication from a cabinet, providing additional storage for a medication, etc. New assignments 1152 may also be processed during, for example, setup of a new edge device, complete reconfiguration of an existing edge device, addition of one or more new medications, etc. Medication stock data may be collected and transmitted to and from system 1100, where medication stock data tracks adding stock and restocking 1148. New stock data may be useful in preventing over/under stocking and historical use patterns withing edge device 1142. Medication transactions 1150 may also be documented and transmitted between system 1100 and edge device 1142. Dispensing of medications 1152 may indicate which medications need to be more frequently accessed, and thus stored in more convenient locations. Return of medications 1154 may also be tracked, and historical trends documented for prevention of overstocking. Waste of medication 1156 may be documented and minimized with alterations to the stock of the wasted medication.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions, and equivalents falling within the spirit and scope of the disclosure, as defined in the appended claims.

The use of the terms “a” and “an” and “the” and similar referents in the context of describing the disclosed embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. Recitation of ranges of values herein are merely intended to serve as a shorthand method of referring individually to each separate value falling within the range, unless otherwise indicated herein and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure

Disjunctive language such as the phrase “at least one of X, Y, or Z,” unless specifically stated otherwise, is intended to be understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present

Although the present disclosure and its advantages have been described in detail, it should be understood that various changes, substitutions and alterations can be made herein without departing from the technology of the disclosure as defined by the appended claims. For example, relational terms, such as “above” and “below” and/or “inside” and “outside” are used with respect to a specific device. Of course, if the device is inverted, above becomes below, and vice versa. Additionally, if oriented sideways, above and below may refer to sides of a device. Further, reference to “first” or “second” instances of a feature, element, or device does not indicate that one device comes before or after the other listed device. Reference to first and/or second devices merely serves to distinguish one device that may be similar or similarly referenced with respect to another device.

Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

The description of the disclosure is provided to enable any person skilled in the art to make or use the disclosure. Various modifications to the disclosure will be readily apparent to those reasonably skilled in the art, and the generic principles defined herein may be applied to other variations without departing from the spirit or scope of the disclosure. Thus, the present disclosure is not intended to be limited to the examples and designs described herein but is to be accorded the widest scope consistent with the principles and novel features disclosed herein. Accordingly, the disclosure is not to be limited by the examples presented herein, but is envisioned as encompassing the scope described in the appended claims and the full range of equivalents of the appended claims.

What is claimed is:

1. A system for determining an optimal configuration for a medication storage cabinet, the system comprising:
one or more processors; and
a memory storing instructions that, when executed by the one or more processors, cause the system to perform operations comprising:
collecting cabinet data and medication data,
preprocessing the collected data, wherein the preprocessing comprises cleaning, normalizing, and transforming the collected data,
performing feature engineering on the preprocessed data to generate engineered features,
selecting relevant features, performing dimensionality reduction on the preprocessed data, and training a machine learning model using the selected features, wherein the machine learning model comprises a random forest model for generating an initial cabinet configuration and a reinforcement learning model for continuous real-time optimization;
generating an optimal configuration for the medication storage cabinet based on the trained machine learning model; and
receiving real-time updates and incorporating feedback to refine the generated optimal configuration.

2. The system of claim 1, wherein the cabinet data comprises bin capacity, temperature zones, and proximity to cooling units, and the medication data comprises volume, temperature sensitivity, security level, hazardous status, and access frequency.

3. The system of claim 1, wherein preprocessing the collected data further comprises handling missing values through statistical imputation, performing error correction, and performing outlier detection.

4. The system of claim 1, wherein performing feature engineering comprises generating interaction features.

5. The system of claim 1, wherein the step of selecting relevant features comprises applying Principal Component Analysis (PCA) to reduce data dimensionality.

6. The system of claim 1, wherein the random forest model is configured to provide an initial configuration by analyzing historical medication placement data and usage patterns.

7. The system of claim 1, wherein the reinforcement learning model is configured to continuously refine the optimal configuration by monitoring real-time data from sensors placed within the cabinet.

8. The system of claim 1, wherein generating the optimal configuration comprises assigning medications to specific bins based on accessibility needs, such that frequently accessed medications are stored in easily accessible bins.

9. The system of claim 1, wherein the processor is further configured to generate alerts based on an analysis via the reinforcement learning model to notify users when a medication should be relocated due to updated usage patterns.

10. The system of claim 1, wherein the machine learning model further comprises a deep learning model to predict future medication placement needs based on seasonal variations in medication demand.

11. A method for determining an optimal configuration for a medication storage cabinet, the method comprising:
collecting cabinet data and medication data,
preprocessing the collected data, wherein the preprocessing comprises cleaning, normalizing, and transforming the collected data,
performing feature engineering on the preprocessed data to generate engineered features,
selecting relevant features, performing dimensionality reduction on the preprocessed data, and training a machine learning model using the selected features, wherein the machine learning model comprises a random forest model for generating an initial cabinet configuration and a reinforcement learning model for continuous real-time optimization;
generating an optimal configuration for the medication storage cabinet based on the trained machine learning model; and
receiving real-time updates and incorporating feedback to refine the generated optimal configuration.

12. The method of claim 11, wherein the cabinet data comprises bin capacity, temperature zones, and proximity to cooling units, and the medication data comprises volume, temperature sensitivity, security level, hazardous status, and access frequency.

13. The method of claim 11, wherein preprocessing the collected data further comprises handling missing values through statistical imputation, performing error correction, and performing outlier detection.

14. The method of claim 11, wherein performing feature engineering comprises generating interaction features.

15. The method of claim 11, wherein the step of selecting relevant features comprises applying Principal Component Analysis (PCA) to reduce data dimensionality.

16. The method of claim 11, wherein the random forest model is configured to provide an initial configuration by analyzing historical medication placement data and usage patterns.

17. The method of claim 11, wherein the reinforcement learning model is configured to continuously refine the optimal configuration by monitoring real-time data from sensors placed within the cabinet.

18. The method of claim 11, wherein generating the optimal configuration comprises assigning medications to specific bins based on accessibility needs, such that frequently accessed medications are stored in easily accessible bins.

19. The method of claim 11, further comprising generating alerts based on an analysis via the reinforcement learning model to notify users when a medication should be relocated due to updated usage patterns.

20. The method of claim 11, wherein the machine learning model further comprises a deep learning model to predict future medication placement needs based on seasonal variations in medication demand.
